(19) United States
(12) Patent Application Publication
(10) Pub. No.: US 2015/0359120 A1
(43) Pub. Date: Dec. 10, 2015

(54) CONVERTIBLE PORTFOLIO COVER FOR A PORTABLE ELECTRONIC DEVICE

(71) Applicant: Chen-Yuan Huang, Taichung City (TW)

(72) Inventor: Chen-Yuan Huang, Taichung City (TW)

(21) Appl. No.: 14/298,977

(22) Filed: Jun. 9, 2014

(51) Int. Cl. H05K 5/03; A45C 13/00; H05K 5/02; A45C 11/00

(52) U.S. Cl. CPC H05K 5/03; A45C 11/00; A45C 13/005; H05K 5/0226; H05K 5/0204; A45C 2011/003

(57) ABSTRACT

A convertible portfolio cover for a portable electronic device. The cover generally includes a folio body and a supporting sheet. The folio body has a base panel and a backrest panel hingedly connected to a rear edge of the base panel for securely holding the portable electronic device. The supporting sheet has a base portion and a brace portion hingedly connected to the base portion. The base portion is generally overlapped with the base panel of the folio body and is displaceable with respect to the base panel. The brace portion has a hinged end hingedly connected to the base portion and an opposite fixed end securely fixed to a rear side of the backrest panel of the folio body. In this manner, the supporting sheet is operable from a retracted position to an extended position, allowing the portable electronic device to be supported in an inclined relation to the base portion.

### BACKGROUND OF THE INVENTION

1. Field of the Invention

The present invention relates to a portfolio cover for a portable electronic device that offers protection for the portable electronic device and more particularly to a convertible portfolio cover that can also be converted to serve as a variable-angle support stand for a portable electronic device during non hand-held use.

2. Description of the Related Art

Portable electronic devices, such as tablet computers, are becoming more popular and there is a demand for convenient carrying cases which offer easy access as well as protection for the devices. A tablet computer commonly is substantially flat, and therefore, the user commonly either lays the tablet computer on a flat surface, or manually holds the tablet computer in front of the user to position the tablet computer for optimal visibility. Traditional protective cases have not offered the versatility to convert the carrying case into a portable hand-held workstation, for easy on-the-go use. There is therefore a need for providing a variable-angle support stand for such devices during non hand-held use. This need is met by the present invention.

### SUMMARY OF THE INVENTION

Accordingly, it is an object of the present invention to provide a convertible portfolio cover for a portable electronic device, which can protect such devices from damage and provide support for operating such device from a desktop or similar flat surface.

To achieve the foregoing objective, the convertible portfolio cover generally includes a folio body and a supporting sheet movably mounted on the folio body. The folio body has a base panel and a backrest panel hingedly connected to a rear edge of the base panel for securely holding the portable electronic device. The supporting sheet has a base portion and a brace portion hingedly connected to the base portion. The base portion is generally overlapped with the base panel of the folio body and is displaceable with respect to the base panel. The brace portion has a hinged end hingedly connected to the base portion and an opposite fixed end securely fixed to a rear side of the backrest panel of the folio body. In such a manner, the supporting sheet is operable between a retracted position where the base portion and the brace portion are substantially respectively overlapped with the base panel and the backrest panel, and an extended position where the base portion is at least partly withdrawn from the base panel to have the backrest panel, the base portion and the brace portion cooperate together to form a triangular support structure, allowing the portable electronic device to be supported in an inclined relation to the base portion.

Specifically, the base panel of the folio body defines a cavity in the rear edge thereof where the base portion of the supporting sheet is displaceably inserted. When the supporting sheet is in the retracted position, the base portion of the supporting sheet is substantially received in the cavity of the base panel; and when the supporting sheet is in the extended position, the base portion is at least partly withdrawn from the cavity of the base panel.

Moreover, a built-in wireless keyboard may be embedded in the base panel of the folio body and designed to allow an user to communicate with the portable electronic device.

Further benefits and advantages of the present invention will become apparent after a careful reading of the detailed description with appropriate reference to the accompanying drawings.

### BRIEF DESCRIPTION OF THE DRAWINGS

FIG. 1 is a perspective view of a convertible portfolio cover in a closed position in accordance with one embodiment of the present invention;

FIG. 2 is a view similar to FIG. 1 depicting the convertible portfolio cover is being released by the locking member (15);

FIG. 3 is a front perspective view of the convertible portfolio cover in its open position supporting a portable electronic device shown in phantom for viewing;

FIG. 4 is a rear perspective view of the convertible portfolio cover shown in FIG. 3;

FIG. 5 is a view similar to FIG. 4 of the present invention in which a written instrument holder is used to hold a pen (7) as depicted;

FIG. 6 is a side view of the convertible portfolio cover, depicting the cover is angled by the user until an optimum viewing angle is achieved;

FIG. 7 is a view similar to FIG. 6, depicting the cover is securely held in the opened position by the supporting sheet (4);

FIG. 8 is a view similar to FIG. 7, depicting the cover is further angled to be held at another angle;

FIG. 9 is a perspective view of the cover shown in FIG. 8;

FIG. 10 is another perspective view of the cover shown in FIG. 9, taken from an angle; and

FIG. 11 is an exploded perspective view of an alternative embodiment of the present invention in which an inside rigid plate (6) is employed.

### DETAILED DESCRIPTION OF EMBODIMENTS

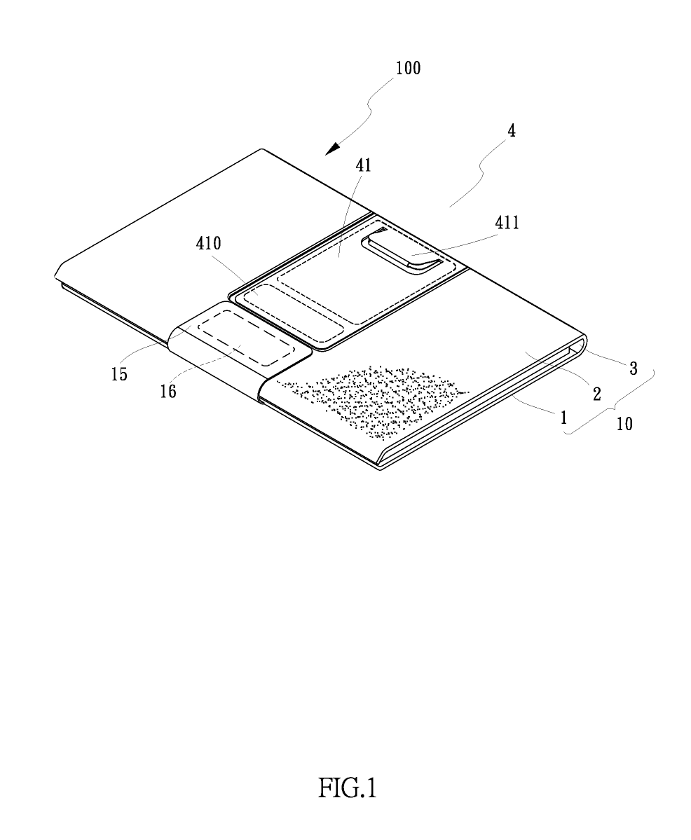

Illustrated in the drawings is a convertible portfolio cover 100 employing the invention. The cover 100 is adapted to offer protection for a portable, generally rectangular electronic device 5, such as a tablet computer, and to provide a variable-angle support stand for that device during non hand-held use. In the embodiment of the cover 100 shown in FIGS. 1-10, the cover 100 includes a foldable folio body 10 and a foldable supporting sheet 4 movably mounted on the folio body 10.

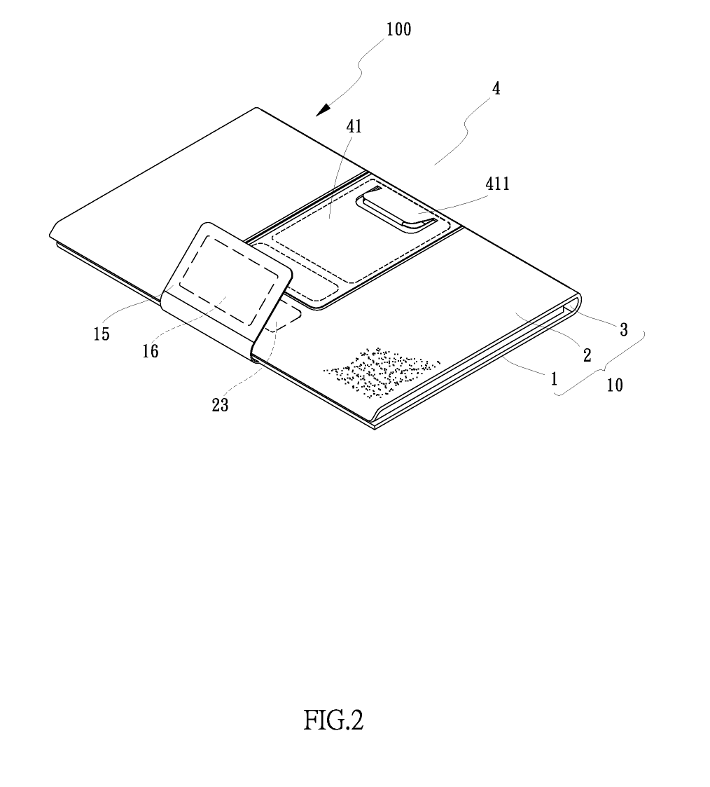

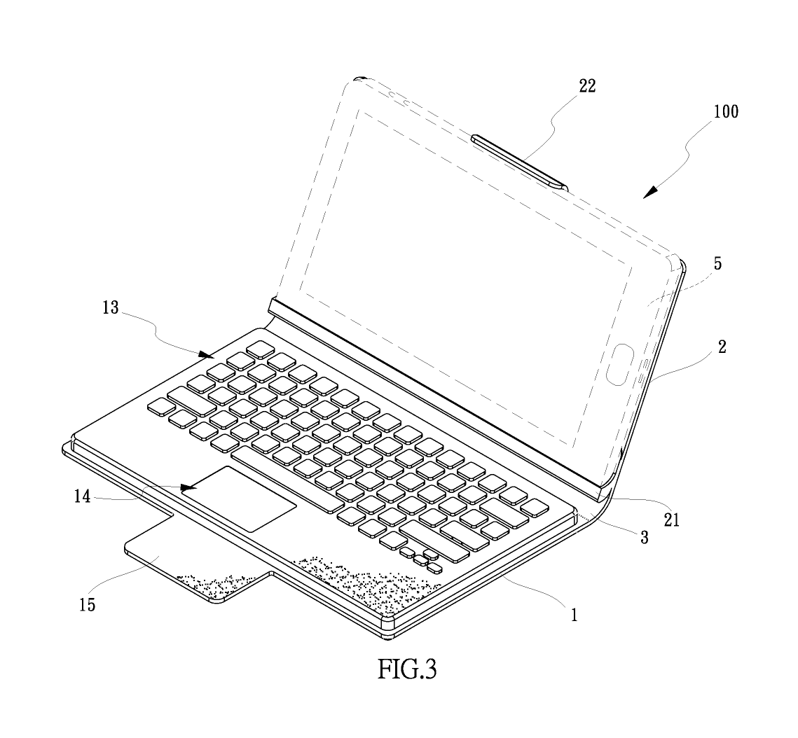

Referring to FIG. 3, the folio body 10 includes a base panel 1, a backrest panel 2 and a transversely extending thin integral web 3 by which the base panel 3 is hingedly connected to a rear edge of the base panel 1. The base panel 1 is integrally formed with a flap 15 at a front edge thereof. Referring back to FIG. 2, the flap 15 of the base panel 1 and the backrest panel 2 are made of a magnetic sheet material with oppositely polarized areas 16, 23 so that the flap 15 when folded over the rest of the base panel 1 to the backrest panel 2 is drawn towards the backrest panel 2 to lock the cover 100, as best shown in FIG. 1.

In particular, the backrest panel 2 is integrally formed with a forwardly projecting flange 21 transversely along one hinged end of the backrest panel 2, which is hingedly connected to the base panel 1, to provide support underneath one end of the portable electronic device 5 shown in phantom. Moreover, the backrest panel 2 is integrally formed at an opposite end thereof with a forwardly projecting bumper 22 substantially parallel to the forwardly projecting flange 21 and being in an arcuate shape so as to capture the other end of the portable electronic device 5. In this way, the portable electronic device 5 can be securely held by the backrest panel 2.

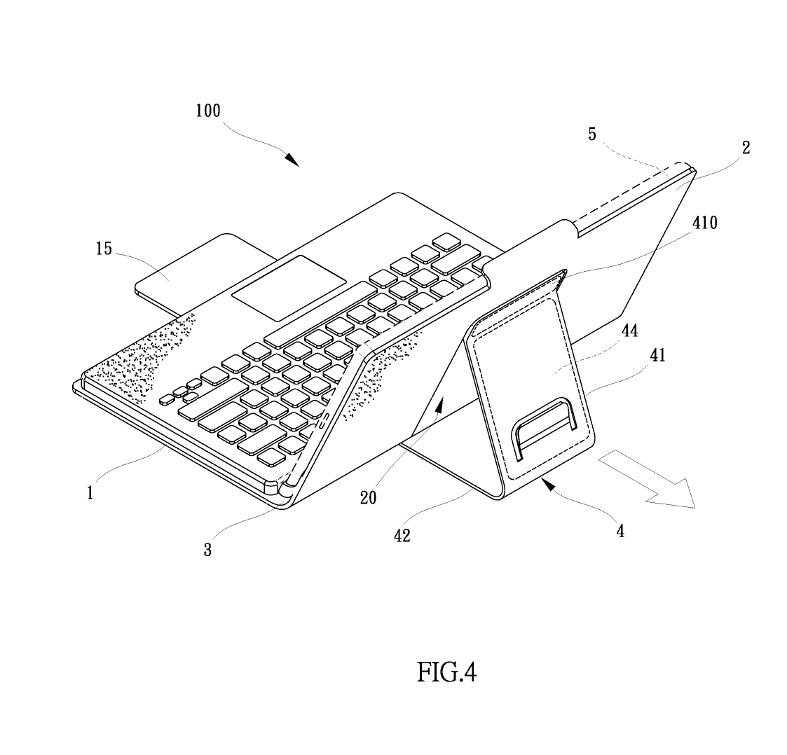

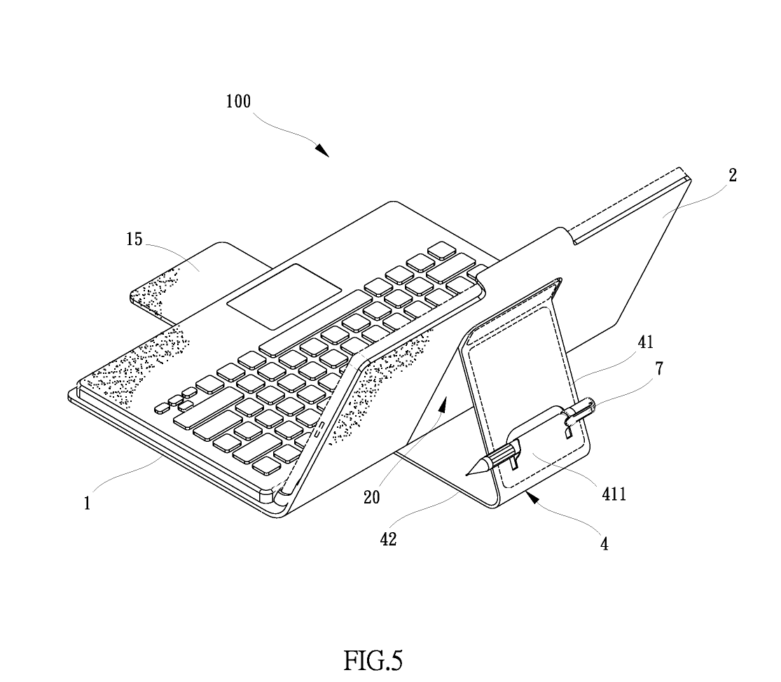

As apparent from FIGS. 1 and 4, the supporting sheet 4 includes a brace portion 41 having a fixed end 410 securely fixed to a rear side of the backrest panel 2 of the folio body 10. The supporting sheet 4 further includes a base portion 42 hingedly connected to an opposite hinged end of the brace portion 41. A recessed cutout 20 may be defined in the rear side of the backrest panel 2 and shaped to receive the brace portion 41 of the supporting sheet 4, allowing the brace portion 41 to be substantially flushed with the rear side of the backrest panel 2 when the cover is in a closed position, as shown in FIG. 1. Besides, the brace portion 41 may be integrally formed at a rear side thereof with an writing instrument holder 411 for holding a pen or a stylus, as illustrated in FIG. 5.

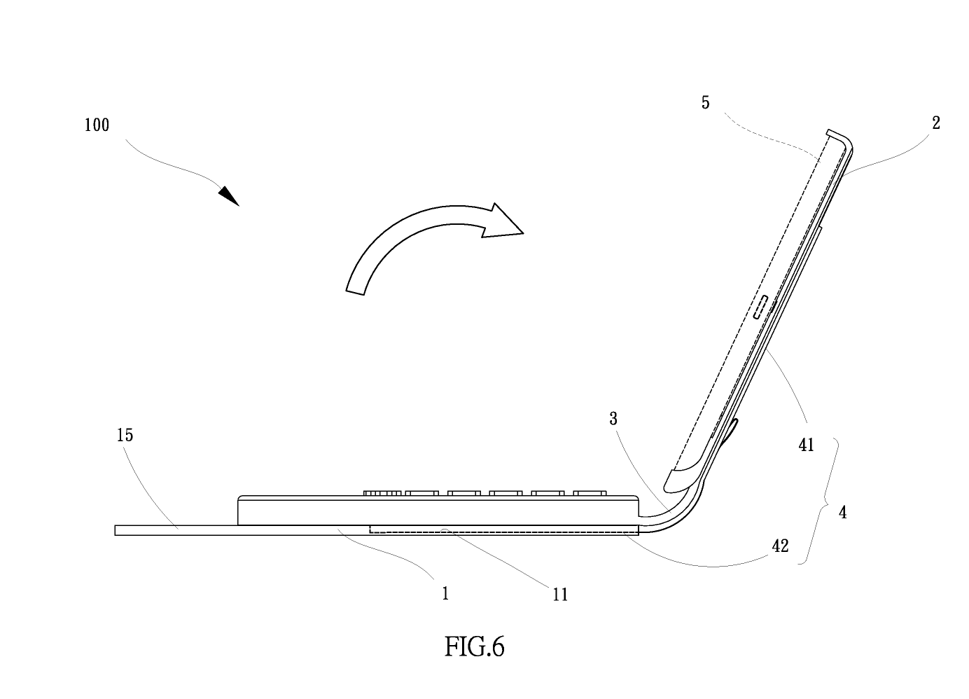

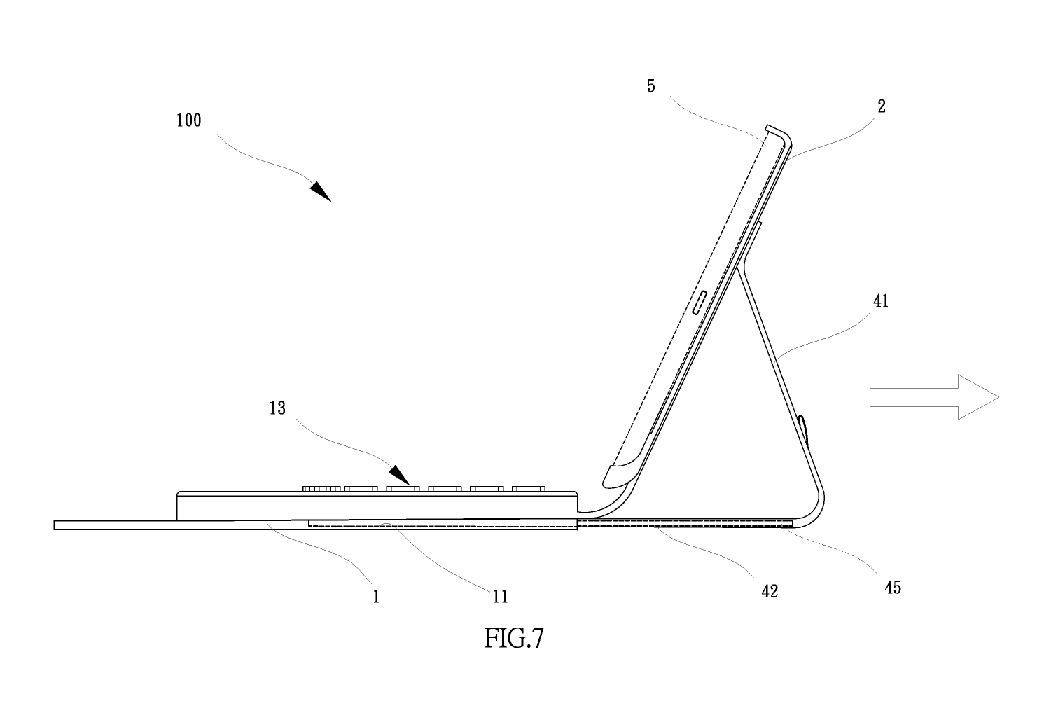

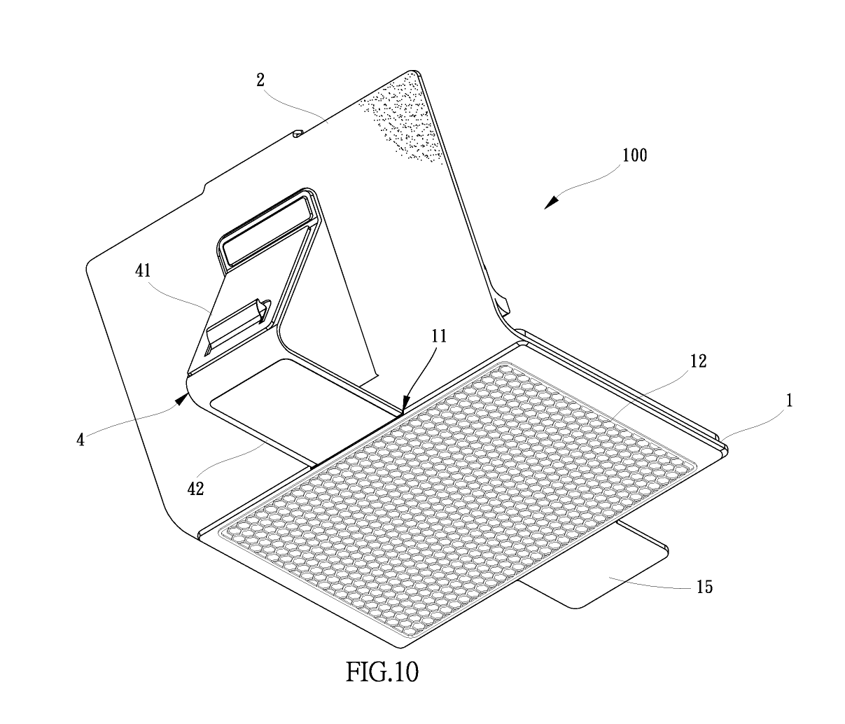

The base portion 42 of the supporting sheet 4 is generally overlapped with the base panel 1 of the folio body 10 and is displaceable with respect to the base panel 1. As shown in FIG. 6 and referring to FIG. 10, the base panel 1 of the folio body 10 defines a cavity 11 in the rear edge thereof where the base portion 42 of the supporting sheet 4 is inserted. In this manner, the supporting sheet 4 is operable between a retracted position, as depicted in FIG. 6, and an extended position, as depicted in FIG. 7. When the supporting sheet 4 is in the retracted position, the base portion 42 is substantially received in the cavity 11 of the base panel 1 and overlapped with the base panel 2 while the brace portion 41 is completely attached to the rear side of the backrest panel 1 of the folio body 1. However, when the supporting sheet 4 is in the extended position, the base portion 42 is partly withdrawn from the cavity 11 of the base panel 1 to have the backrest panel 2, the base portion 42 and the brace portion 41 cooperate together to form a triangular support structure, as shown in FIG. 7, allowing the portable electronic device 5 to be supported in an inclined relation to the base portion 42 or a working surface. The portable electronic device 5 can therefore be held by the cover 100 at a viewing angle comfortable to the user.

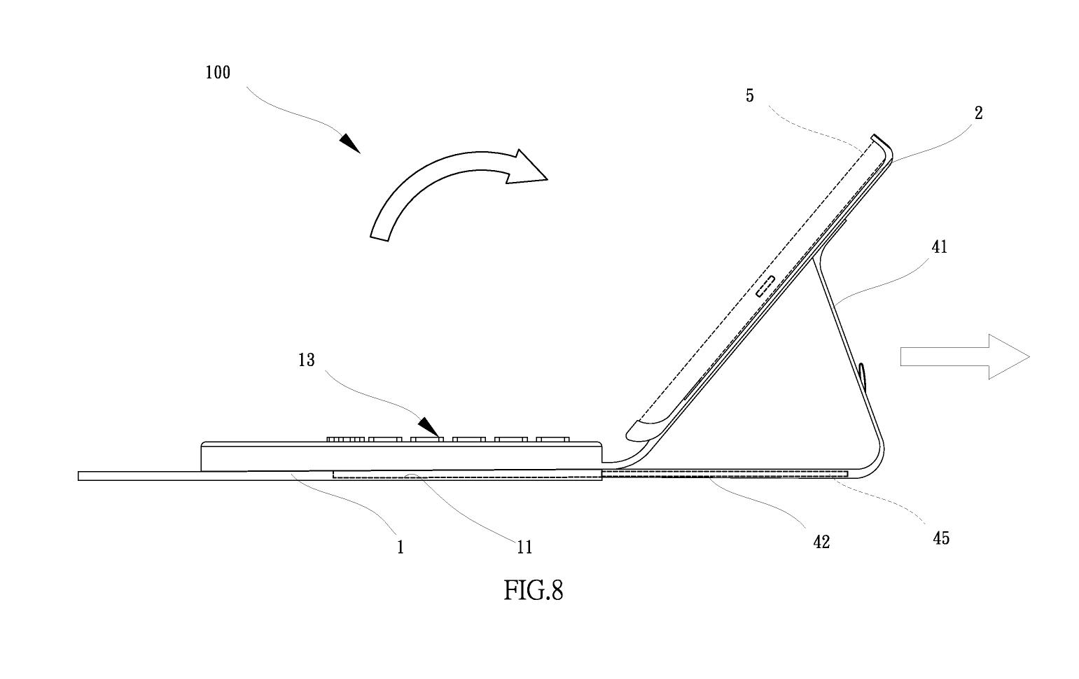

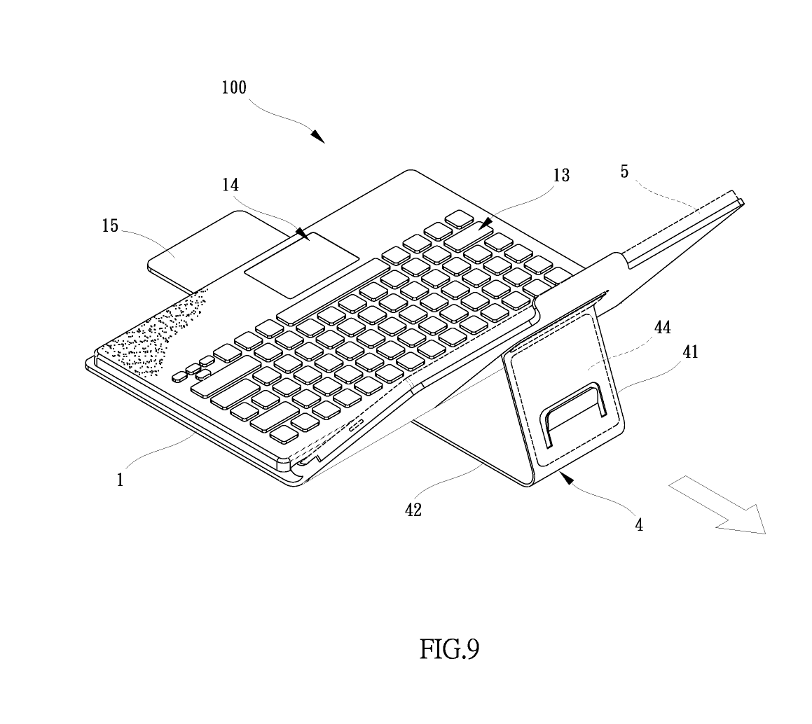

In addition, the base portion 42 of the supporting sheet 4 may be further withdrawn from the cavity 11 of the base panel 1 to have the supporting sheet 4 move to a second extended position, as shown in FIG. 8 or 9, where the portable electronic device 5 is oriented at another viewing angle. Because the base portion 42 of the supporting sheet 4 is displaceable with respect to the base panel 1 of the folio body 10, an infinite number of viewing angles are obtainable. Particularly, once the lower end of the portable electronic device 5 is secured by the projecting flange 21 of the backrest panel 2, the portable electronic device 5 may be angled anywhere from a substantially vertical position to a substantially horizontal position. Preferably, the portable electronic device 5 is oriented at an angle that facilitates viewing while operating a keyboard 13 or a touch pad 14. Note that the keyboard 13 is a built-in wireless keyboard embedded in the base panel 1 of the folio body 10, and is designed to allow an user to communicate with the portable electronic device 5. Similarly, the touch pad 14 is a built-in wireless touchpad embedded in the base panel 11 of the folio body 10 and adjacent to the keyboard 13. The wireless touchpad 14 is also designed to allow the user to communicate with the portable electronic device 5 in a known manner.

As shown in FIGS. 7 and 9, a stiff middle layer 44, 45 may be employed in each of the brace portion 41 and the base portion 42 of the supporting sheet 4 to provide structural support to the latter. Moreover, as shown in FIG. 10, a skidproof pad 12, such as a honeycomb mesh, may be attached to a bottom surface of the base panel 1 of the folio body 10 to frictionally restrain the cover 100 against sliding movement when it is resting on the work surface.

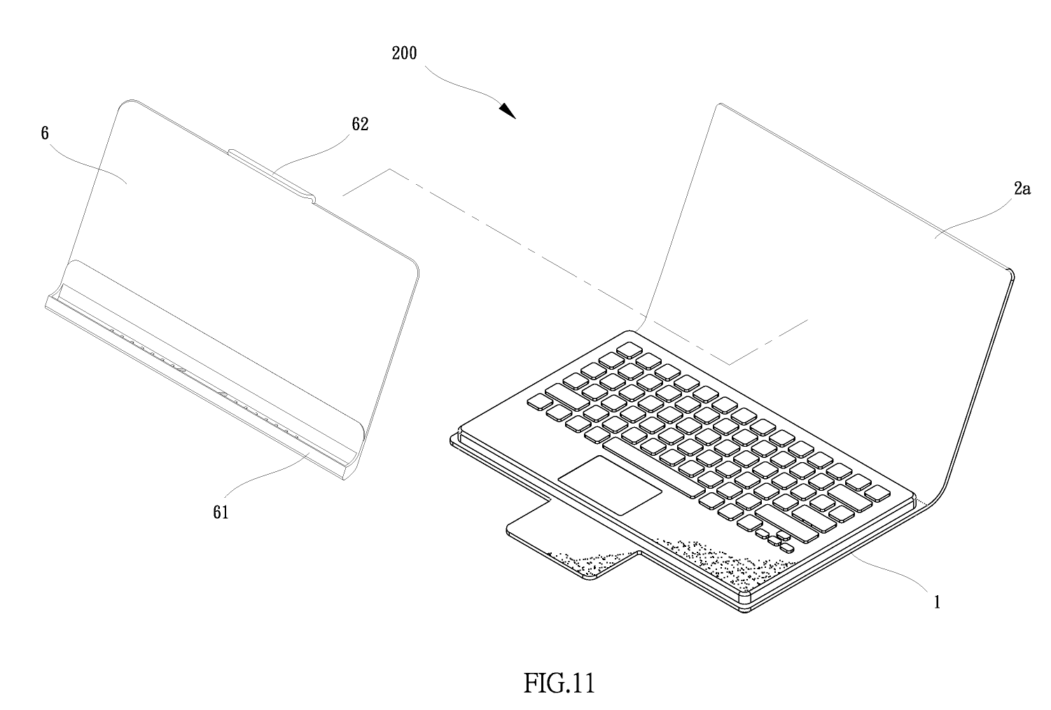

Referring now to FIG. 11, there is shown an alternate embodiment 200. Embodiment 200 is similar to embodiment 100, except that a two-ply lamination of an outside backing layer 2a and an inside rigid plate 6 is provided in lieu of the one-piece backrest panel 2 of the aforementioned cover 100. The outside backing layer 2a has an hinged end hingedly connected to the base panel 1. The inside rigid plate 6 is bonded to the outside backing layer 2a by adhesive. Moreover, a forwardly projecting flange 61 is integrally formed on the inside rigid plate 6 and transversely along the hinged end of the outside backing layer 2a to provide support underneath one end of the portable electronic device (not shown in FIG. 11). And, the inside rigid plate 6 is further integrally formed with a forwardly projecting bumper 62 substantially parallel to the forwardly projecting flange 61. The bumper 62 is in an arcuate shape so as to capture the other end of the portable electronic device.

As described above, the cover 100 or 200 of the present invention can offer protection for a portable electronic device, and by which the need for providing a variable-angle support stand for the portable electronic device during non hand-held use is fulfilled.

What is claimed is:

1. A convertible portfolio cover for a portable electronic device, comprising:
a folio body having a base panel and a backrest panel hingedly connected to a rear edge of the base panel for securely holding the portable electronic device; and
a supporting sheet having a base portion and a brace portion hingedly connected to the base portion; wherein the base portion is generally overlapped with the base panel of the folio body and is displaceable with respect to the base panel, and the brace portion has a hinged end hingedly connected to the base portion and an opposite fixed end securely fixed to a rear side of the backrest panel of the folio body in such a way that the supporting sheet is operable between a retracted position where the base portion and the brace portion are substantially respectively overlapped with the base panel and the backrest panel, and an extended position where the base portion is at least partly withdrawn from the base panel to have the backrest panel, the base portion and the brace portion cooperate together to form a triangular support structure, allowing the portable electronic device to be supported in an inclined relation to the base portion.

2. The convertible portfolio cover of claim 1, wherein the backrest panel is integrally formed with a forwardly projecting flange transversely along one hinged end of the backrest panel, which is hingedly connected to the base panel, to provide support underneath one end of the portable electronic device.

3. The convertible portfolio cover of claim 2, wherein the backrest panel is integrally formed at an opposite end thereof with a forwardly projecting bumper substantially parallel to the forwardly projecting flange, and the bumper is in an arcuate shape so as to capture the other end of the portable electronic device.

4. The convertible portfolio cover of claim 1, wherein the backrest panel includes an outside backing layer having an hinged end hingedly connected to the base panel, and an inside rigid plate bonded to the outside backing layer and formed integrally with a forwardly projecting flange transversely along the hinged end of the outside backing layer to provide support underneath one end of the portable electronic device.

5. The convertible portfolio cover of claim 4, wherein the inside rigid plate of the backrest panel is integrally formed with a forwardly projecting bumper substantially parallel to the forwardly projecting flange, and the bumper is in an arcuate shape so as to capture the other end of the portable electronic device.

6. The convertible portfolio cover of claim 1, wherein the base panel of the folio body defines a cavity in the rear edge thereof where the base portion of the supporting sheet is displaceably inserted; when the supporting sheet is in the retracted position, the base portion of the supporting sheet is substantially received in the cavity of the base panel; and when the supporting sheet is in the extended position, the base portion is at least partly withdrawn from the cavity of the base panel.

7. The convertible portfolio cover of claim 1, further comprising a built-in wireless keyboard embedded in the base panel of the folio body, the wireless keyboard is designed to allow an user to communicate with the portable electronic device.

8. The convertible portfolio cover of claim 1, further comprising a built-in wireless touchpad embedded in the base panel of the folio body, the wireless touchpad is designed to allow an user to communicate with the portable electronic device.

9. The convertible portfolio cover of claim 1, further comprising a skidproof pad attached to a bottom surface of the base panel of the folio body.

10. The convertible portfolio cover of claim 1, wherein the skidproof pad is a honeycomb mesh.

11. The convertible portfolio cover of claim 10, wherein the base panel of the folio body has a flap at a front edge thereof; the flap of the base panel and the backrest panel are made of a magnetic sheet material with oppositely polarized areas so that the flap when folded over the rest of the base panel to the backrest panel is drawn towards the backrest panel to lock the convertible portfolio cover.

12. The convertible portfolio cover of claim 1, wherein the brace portion of the supporting sheet is integrally formed at a rear side thereof with an writing instrument holder.

13. The convertible portfolio cover of claim 1, wherein the supporting sheet comprises a stiff middle layer in each of the base portion and the brace portion to provide structural support to the base portion and the brace portion of the supporting sheet.

14. The convertible portfolio cover of claim 1, wherein the folio body further comprises a transversely extending thin integral web by which the base panel and the backrest panel are hingedly connected to each other.

15. The convertible portfolio cover of claim 1, wherein the backrest panel of the folio body defines a recessed cutout in a rear side thereof, and the cutout is configured in shape and size to receive the brace portion of the supporting sheet.
